(19) United States
(12) Patent Application Publication
(10) Pub. No.: US 2023/0031489 A1
(43) Pub. Date: Feb. 2, 2023

(54) HERMETIC SURFACE MOUNT PACKAGE FOR SEMICONDUCTOR SIDE EMITTING LASER AND METHOD FORMING SAME

(71) Applicant: Excelitas Canada, Inc., Vaudreuil-Dorion (CA)

(72) Inventors: JinHan Ju, Kirkland (CA); Gabriel Charlebois, Vaudreuil-Dorion (CA)

(73) Assignee: Excelitas Canada, Inc., Vaudreuil-Dorion (CA)

(21) Appl. No.: 17/965,195

(22) Filed: Oct. 13, 2022

Related U.S. Application Data
(63) Continuation of application No. PCT/US2021/027378, filed on Apr. 15, 2021.
(60) Provisional application No. 63/010,460, filed on Apr. 15, 2020.

(51) Int. Cl. H01S 5/02208; H01S 5/02315; H01S 5/02218; H01S 5/02345; H01S 5/02257; H01S 5/40

(52) U.S. Cl. CPC H01S 5/02208; H01S 5/02315; H01S 5/02218; H01S 5/02345; H01S 5/02257; H01S 5/4031

(57) ABSTRACT

A method for manufacturing a hermetic side looking laser surface-mount device (SMD) package includes forming a glass cap. An array of pockets is formed in the first glass wafer. The array of pockets is sealed by bonding a second glass wafer to the first glass wafer. The glass cap is released by singulating the sealed array of pockets.

### CROSS-REFERENCE TO RELATED APPLICATIONS

This application is continuation of International Patent Application Serial No. PCT/US2021/027378, filed on Apr. 15, 2021, entitled “HERMETIC SURFACE MOUNT PACKAGE FOR SEMICONDUCTOR SIDE EMITTING LASER AND METHOD FORMING SAME”, which claims the benefit of U.S. Provisional patent application Ser. No. 63/010,460, filed on Apr. 15, 2020, entitled “HERMETIC SURFACE MOUNT PACKAGE FOR SEMICONDUCTOR SIDE EMITTING LASER AND METHOD FORMING SAME.” The contents of these applications are incorporated by reference herein in their entireties.

### TECHNICAL FIELD

The present disclosure relates to electronic circuitry, and more particularly, is related to surface mount packaging for semiconductor emitters.

### BACKGROUND

Surface-mount technology (SMT) refers to the mounting of electrical components directly onto the surface of a printed circuit board (PCB). An electrical component mounted in this manner is referred to as a surface-mount device (SMD). A SMD may be contrasted with through-hole technology construction for mounting components to a PCB, in large part because SMT allows for increased manufacturing automation. Current SMD packages for side emitting laser are not hermetically sealed, so the laser chip lifetime and package performance are significantly affected.

Presently, hermetic packages for laser diodes are not SMD packages for side emitting lasers, but rather through-hole packages for top-looking lasers, such as a metal can package 160 shown in FIG. 1A. These through hole packages 160 have high material and manufacturing cost, high inductance, and high thermal resistance, making them unsuitable for some applications.

The current leadless chip carrier (LCC) package for side emitting lasers is not a hermetic package. For example, as shown in FIG. 1B, a current SMD package 100, is shown with a chip array of four side emitting semiconductor lasers 140 mounted on a substrate 120 and encapsulated with a transparent resin 150, for example epoxy. However, the encapsulation 150 may be permeable, for example, by moisture and/or contaminants, and therefore the SMD package 100 may not operate reliably over time. Further, the current SMD package 100 may have high inductance and thermal resistance. Therefore, there is a need in the industry to overcome the deficiencies in this area.

### SUMMARY

Embodiments of the present invention provide a hermetic surface mount package for semiconductor side emitting laser and method for forming the same. Briefly described, the present disclosure relates to a method for manufacturing a hermetic side looking laser surface-mount device (SMD) package. A glass cap is formed from a first glass wafer and a second glass wafer. An array of pockets is formed in the first glass wafer and sealed by bonding the second glass wafer to the first glass wafer. The glass cap is released by singulating the sealed array of pockets.

Other systems, methods and features of the present invention will be or become apparent to one having ordinary skill in the art upon examining the following drawings and detailed description. It is intended that all such additional systems, methods, and features be included in this description, be within the scope of the present invention and protected by the accompanying claims.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principals of the invention.

FIG. 1A is a schematic diagram of a hermetically sealed top-looking laser diode through-hole package.

FIG. 1B is a schematic diagram of an encapsulated side-looking laser surface mount package.

FIG. 2 is a schematic diagram of a first embodiment of a hermetically sealed side emitting laser surface mount design package from a perspective view.

FIG. 3A shows the package of FIG. 2 from a top view.

FIG. 3B shows the package of FIG. 2 from a side view.

FIG. 3C shows the package of FIG. 2 from a front (emitting side) view.

FIG. 3D shows the package of FIG. 2 from a bottom (PCB side) view.

FIG. 4A is a schematic cutaway diagram of the package of FIG. 2 from a side view.

FIG. 4B is a schematic cutaway diagram of an alternative embodiment of the package of FIG. 4A.

FIG. 5 is a schematic diagram of a cap portion of the package of FIG. 2 from a perspective view.

FIG. 6 is a flowchart of an exemplary of a method embodiment for manufacturing an SMD laser package.

FIG. 7A is a schematic diagram of a glass cap for the SMD laser package at a first stage of manufacture according to the method of FIG. 6.

FIG. 7B is a schematic diagram of the glass cap for the SMD laser package at a second stage of manufacture according to the method of FIG. 6.

FIG. 7C is a schematic diagram of the glass cap of FIG. 7B indicating two singulation planes.

FIG. 8A is a schematic diagram of the glass cap of the package of FIG. 2 after singulation.

FIG. 8B is a schematic diagram of the glass cap of FIG. 8A showing an optional metallization layer.

FIG. 9 is a schematic diagram of an alternative embodiment of the SMD laser package with sixteen lasers.

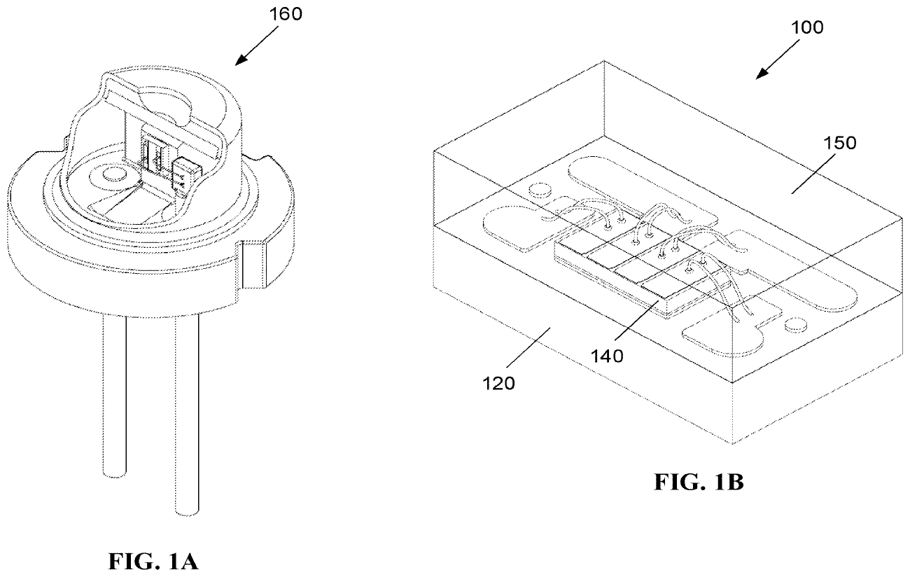

### DETAILED DESCRIPTION

The following definitions are useful for interpreting terms applied to features of the embodiments disclosed herein, and are meant only to define elements within the disclosure.

As used within this disclosure, “substantially” means “very nearly” or to within normal manufacturing tolerances. For example, a substantially parallel surface may be parallel to within acceptable tolerances, or a substantially flat surface is flat to within a specified measure of flatness. Similarly, a substantially undisturbed laser beam refers to a laser beam that is not significantly or noticeably altered (distorted or diverted) beyond acceptable operating tolerances.

As used within this disclosure, a “pocket” refers to a recess formed within a solid object, for example, a recess formed within a glass substrate. In particular, the recess may be formed within a first planar surface of the solid object, so the pocket has a single contiguous opening in the first planar surface of the solid object, while not extending through any other surface of the solid object.

As used within this disclosure, a “wafer” refers to a substrate, generally referring to a substrate of a single material, for example, a glass wafer.

Reference will now be made in detail to embodiments of the present invention, examples of which are illustrated in the accompanying drawings. Wherever possible, the same reference numbers are used in the drawings and the description to refer to the same or like parts.

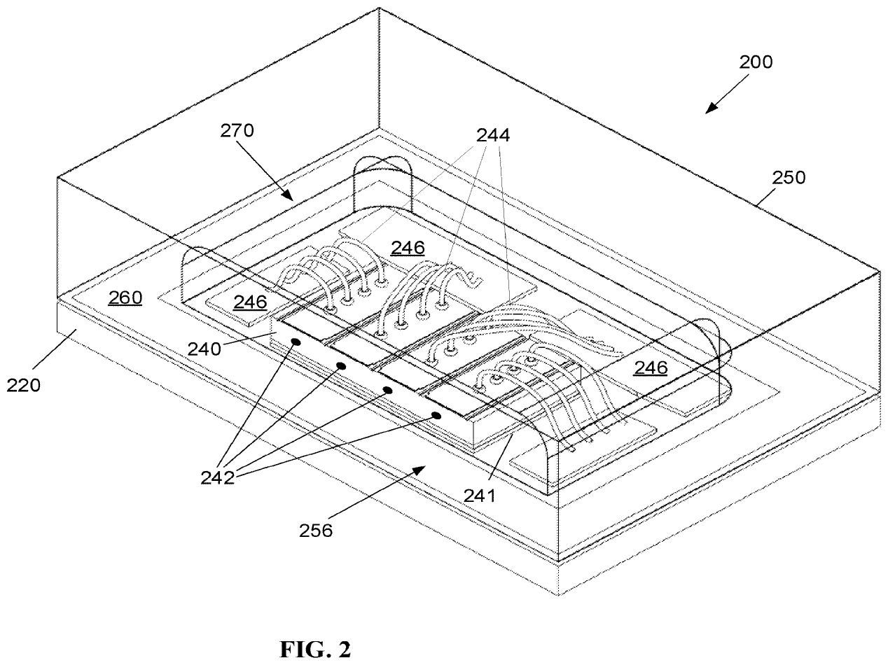

Exemplary embodiments of the present invention include devices and methods for producing a hermetic SMD package for one or more side emitting lasers. Such embodiments are suitable for high reliability requirements such as operation at high temperature with high humidity, as a non-limiting example, on the order of 85° C. and 85% relative humidity for 1000 hours. FIG. 2 shows a perspective view of an exemplary first embodiment of a hermetic SMD package 200 having a laser array die 240 having four side emitter laser diodes, each laser diode having a side aperture 242 for emission of a laser beam in a direction substantially parallel to a package substrate 220 mounting surface. The substrate 220 serves as a carrier for the laser die 240 and associated circuitry for use in conjunction with the laser array die 240, for example, control circuitry and circuitry to provide sufficient power for operation of the laser array die. The substrate 220 may be formed from a hermetic material, for example but not limited to, glass or ceramic such as AlN (Aluminum Nitride) having a thermal conductivity range of 170 to 250 W/m-K. The laser die 240 may be attached to the substrate 220 at a conductive die attach pad 241 disposed upon the substrate 220.

The package 200 includes a cap 250, for example a glass cap transparent to light emitted by the laser die array 240 attached to the substrate 220. The cap 250 includes a cavity 270 arranged to enclose the laser array die 240 and associated circuitry within a hermetically sealed chamber bounded by the cap 250 and the substrate 220. The cap 250 may be attached and sealed to the substrate 220 at a base portion of the cap 250 surrounding the cavity 270 to a perimeter of a component mounting surface of the substrate 220. For example, the cap 250 may be directly attached to the substrate 220 with frit glass or by laser welding. Optionally, a metallization layer 260 may be added to a base portion of the cap 250 surrounding the cavity 270 so the metallization layer 260 may be attached to the substrate 220 by soldering the metallization layer 260 to the metallized substrate 220. For example, the metallization layer 260 may be applied to the cap 250 by a sputtering process.

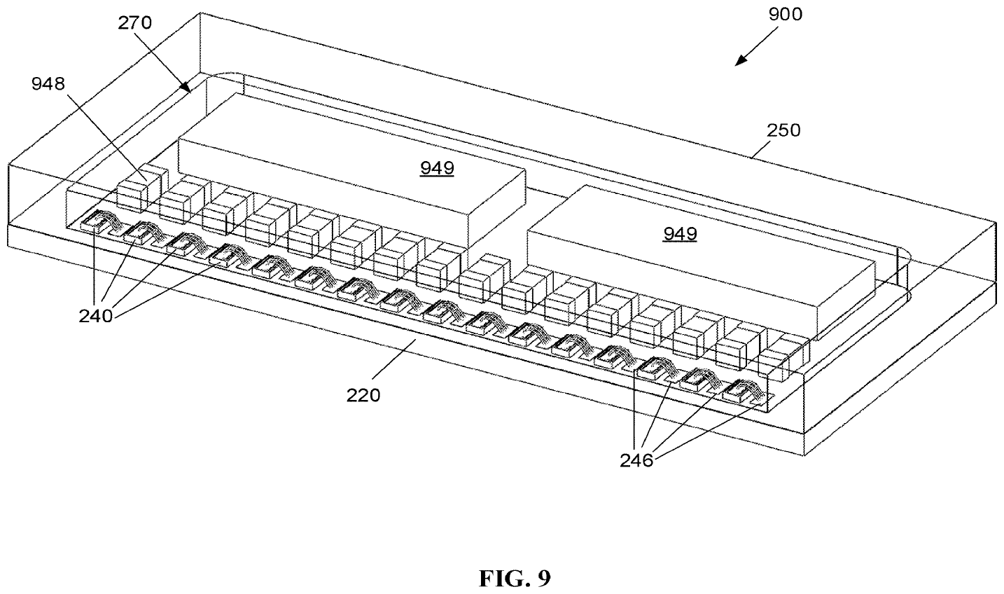

Additional circuitry associated with the laser die 240 may also be situated on the substrate 220 within the cavity 270, for example, a plurality of wire bond pads 246 attached to the substrate 220, and a plurality of bond wires 244 electrically connecting the laser array die 240 to the wire bond pads 246. In alternative embodiments, for example, an alternative embodiment with sixteen laser chips as shown in FIG. 9, an SMD package 900 may include other circuit components mounted within the cavity 270, for example, capacitors 948, driver circuitry 949, for example, transistors, and the like.

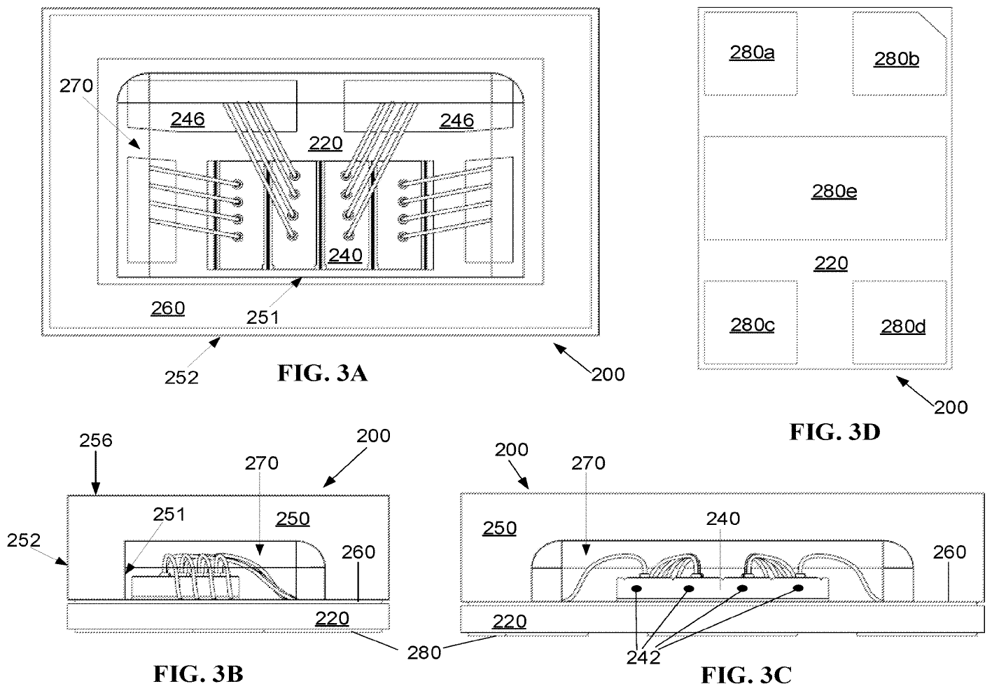

FIGS. 3A-3D show different views of the first embodiment package 200. FIG. 3A shows the package 200 from a top view. FIG. 3B shows the package 200 from a side view. FIG. 3C shows the package 200 from a front (emitting side) view. FIG. 3D shows the package 200 from a bottom (mount side) view.

As shown in FIG. 3D, a bottom surface of the package 200 has a plurality of metal pads 280a-280e mounted to a bottom (PCB mounting) surface of the substrate 220. The metal pads 280a-280e are in electrical and/or thermal communication with the laser array die 240 bottom surface (opposite the wire bond connections) and to the wire bond pads 246, for example by sealed through vias (not shown) passing through the substrate 220. The metal pads 280a-280e provide external electrical and thermal connectivity to the package 200.

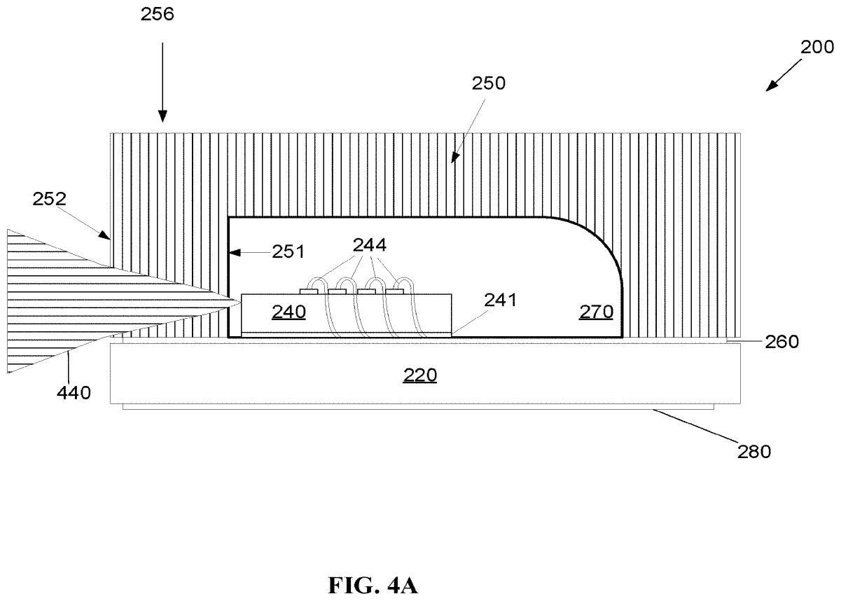

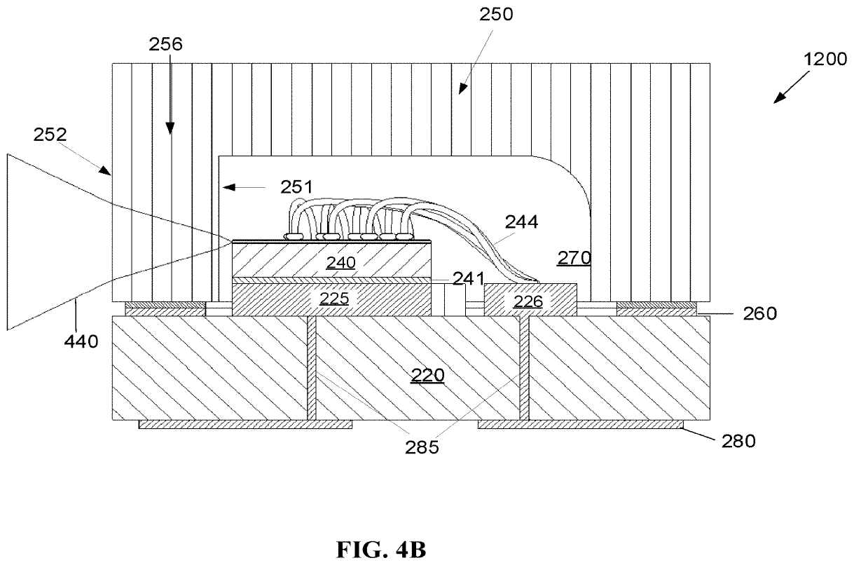

As shown by FIG. 4A, the side emitting laser diodes of the laser array die 240 are oriented to emit laser beams 440 through a flat window 256 (FIG. 3B) in the cap 250. The flat window 256 is oriented in a plane substantially normal to a path 440 (FIG. 4A) of the laser beams 440 emitted by the laser array die 240. The flat window 256 is optically flat on both a first surface 251 (light receiving surface 251) on the interior of the cap 250 (cavity side) and a second surface 252 (light emitting surface 252) on the exterior of the cap 250 so as not to substantially disturb the laser beam 440 (FIG. 4A), for example so that the laser beam 440 (FIG. 4A) is not detrimentally distorted, diffracted, and/or diverted. The first surface 251 and/or the second surface 252 of the flat window 256 may be treated with an anti-reflective (AR) coating, for example silicon dioxide, for high light transmittance.

In an alternative embodiment shown in FIG. 4B, a package 1200 is substantially similar to the package 200 of FIG. 4A, with the addition of an electrically and/or thermally conductive metal laser array pedestal 225 is disposed between the substrate 220 and the laser array die 240. The laser array pedestal 225 may be, for example, on the order of 100 microns thick, positioning the laser array die 240 above the rest of the substrate 220 by 100 microns, for example, to avoid or minimize a lower portion of the laser light beam 440 being clipped by the edge of glass cap 250 or the edge of substrate 220. An electrically and/or thermally conductive die attach pad 241 may be disposed between the laser array die 240 and the metal laser array pedestal 225. Other pedestals may similarly be included, for example a wire bond pedestal 226. The pedestals 225, 226 may be electrically connected to the metal pads 280 by metalized through vias 285.

Alternative embodiments of the package 200, 1200 may have a single side emitting laser diode instead of a laser diode array die 240 or may have an array die 240 with a different number of laser diodes, for example, two, eight, or sixteen, or more laser diodes, as shown in FIG. 9.

The protection provided by the hermetically sealed package 200, 1200 may significantly extend the working lifetime and/or laser performance of the laser die array 240. This is desirable in several applications, for example, to improve performance and reliability level of side emitting laser packaging for automotive LIDAR (Light Detection and Ranging) applications.

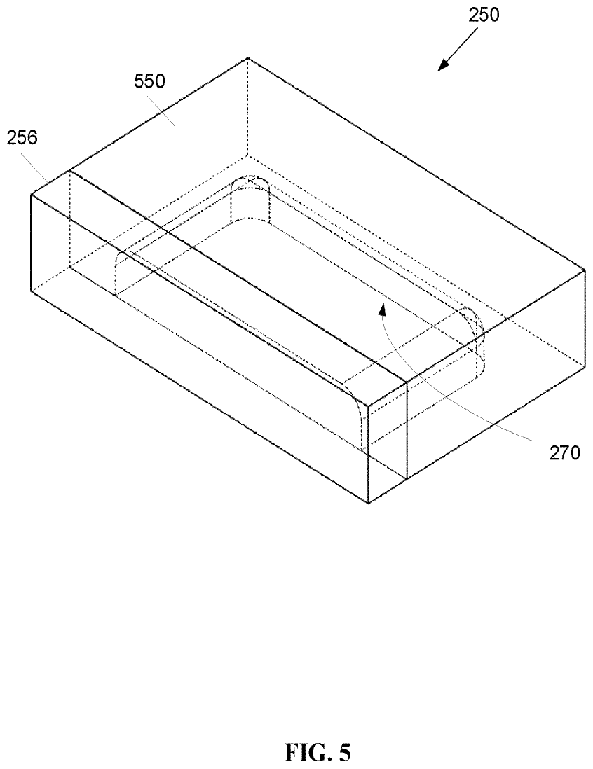

As shown by FIG. 5, the glass cap 250 may be formed of two or more pieces of glass that are bonded together, for example, a first portion 550 and a second portion, where the second portion forms the substantially flat window 256. The first portion 550 is at least partially hollowed out, for example by etching or machining, to form the cavity 270. As shown by FIG. 5, the edges of the cavity 270 that are bounded by glass of the first portion 550 of the cap 250 on at least two side may be rounded. Further the planar surfaces of the walls of the cavity 270 within the first portion 550 of the cap 250 need not be (and practically, are unlikely to be) as flat as the substantially flat window 256, as the laser light 400 (FIG. 4A) is not directed through any surface of the first portion 550 of the cap 250.

Under the first exemplary embodiment, the glass cap may have a length on the order of 3.5 mm, a width on the order of 2.5 mm, and a height on the order of 1 mm. The flat window 256 may have a thickness on the order of 0.5 mm. The cavity 270 may be on the order of 2.5 mm long, 1.4 mm wide, and 0.6 mm deep. Of course, the size of the package and the cavity may be scaled and/or reproportioned according to the number of laser dies in the package and its application at hand.

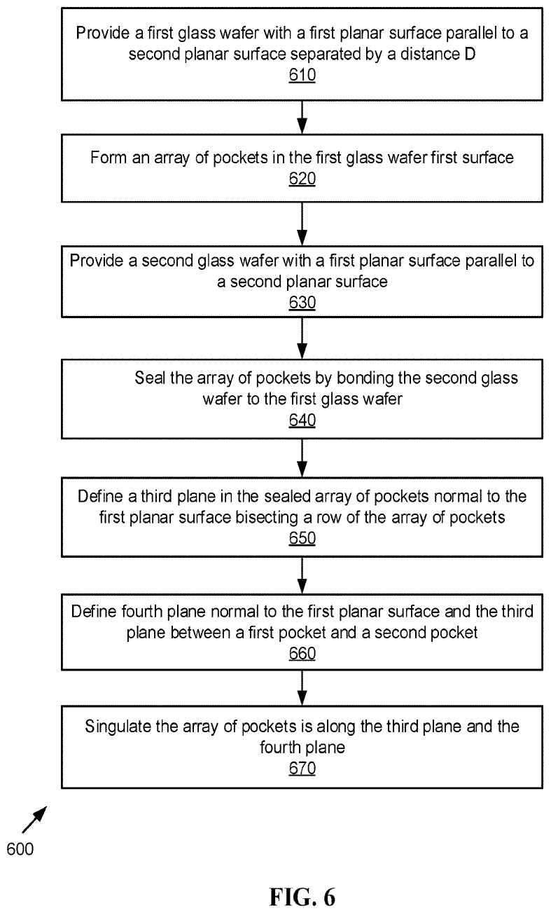

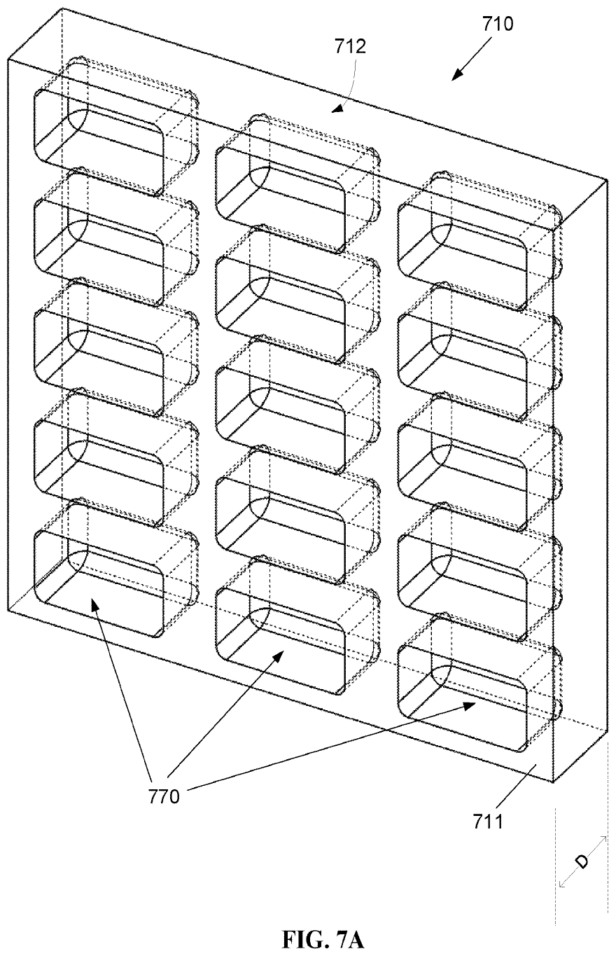

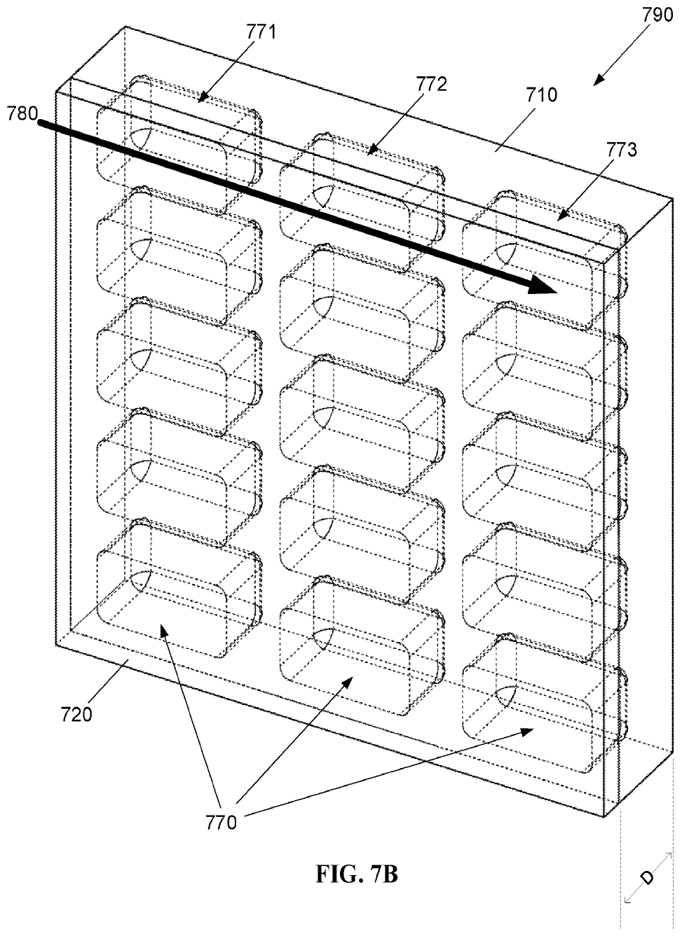

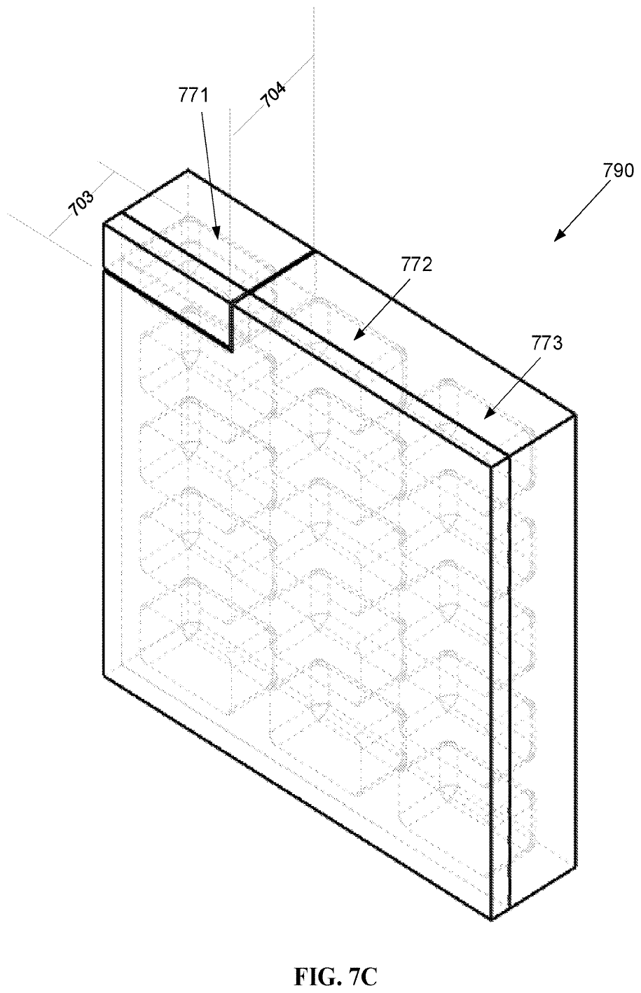

FIG. 6 is a flowchart 600 for a first exemplary method embodiment for manufacturing a glass cap for a hermetic side looking laser SMD package. It should be noted that any process descriptions or blocks in flowcharts should be understood as representing modules, segments, portions of code, or steps that include one or more instructions for implementing specific logical functions in the process, and alternative implementations are included within the scope of the present invention in which functions may be executed out of order from that shown or discussed, including substantially concurrently or in reverse order, depending on the functionality involved, as would be understood by those reasonably skilled in the art of the present invention. The method is described with reference to FIGS. 7A-7C.

A first glass wafer 710 is provided, as per block 610. The first glass wafer has a first planar surface 711 and a second planar surface 712 substantially parallel to the first planar surface. The second planar surface 712 is disposed at a distance D from the first planar surface 711 in a direction substantially normal to the first planar surface 711. An array having a plurality of pockets 770 is formed in the first glass wafer first surface 711, as shown by block 620. The pockets 770 are cut into the first glass wafer first surface 711 but are not deep enough to extend to the first wafer second surface 712. Each of the pockets 770 may be substantially rectangular in profile. As shown in FIG. 7A, the edges and corners of each of the pockets 770 may be rounded, however in alternative embodiments the edges may be sharply defined. The pockets 770 do not extend through any surface of the first glass wafer 710 other than the first glass wafer first planar surface 711.

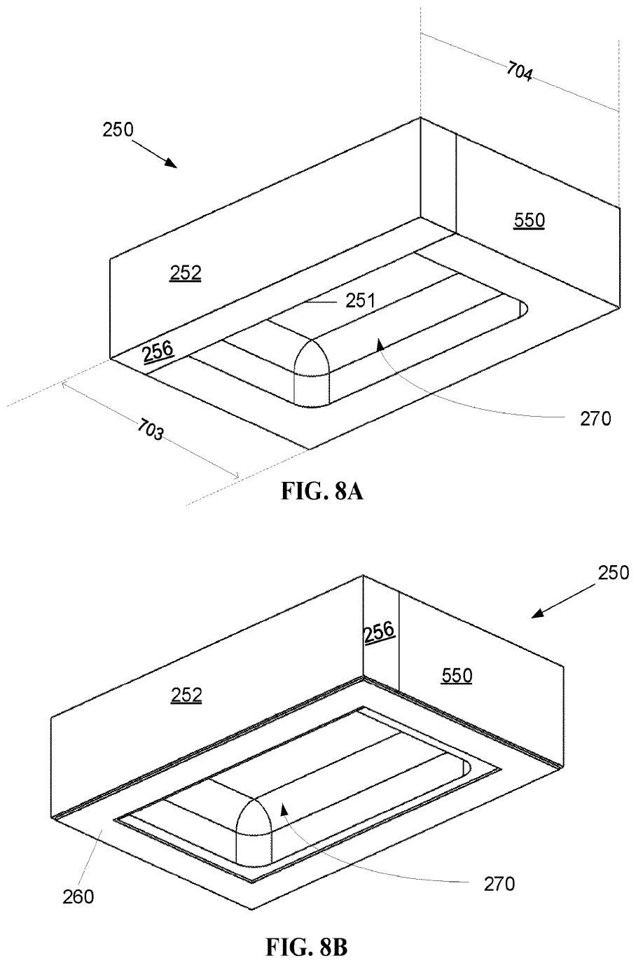

A second glass wafer 720 (FIG. 7B) is provided with a first planar surface 251 and a second planar surface 252 substantially parallel to the first planar surface, as shown by block 630. The array of pockets 770 is sealed by bonding the second glass wafer 720 to the first glass wafer 710, as shown by block 640, forming an array of sealed pockets 790. A plurality of glass caps 250 (FIG. 8A) may be formed by singulating the array of sealed pockets 790, as described below.

As shown by FIG. 7C, A third plane 703 is defined in the array of sealed pockets 790 normal to the first planar surface, bisecting a row 780 (FIG. 7B) of the array of sealed pockets 790 (FIG. 7B), as shown by block 650. A fourth plane 704 (FIG. 7C) is defined normal to the first planar surface 711 (FIG. 7A) and to the third plane 703 between a first pocket 771 and a second pocket 772, as shown by block 660. The array of sealed pockets 790 is singulated along the third plane 703 and the fourth plane 704, as shown by block 670, releasing a glass cap 250 (FIG. 8A) from the array of sealed pockets 790.

FIG. 8A is a schematic diagram of the glass cap 250 of the package 200 after the singulation as per FIG. 6. Relating FIG. 8A to the first embodiment 200 (FIG. 2), FIG. 8A shows the glass cap 250 after singulation. After singulation, a singulated portion of the second glass wafer 720 (FIG. 7B) forms the flat window 256 of the glass cap 250, and a singulated portion of the first glass wafer 710 (FIG. 7A) forms the reminder of the glass cap 250. The bisected pocket 770 of the sealed array of pockets forms the cavity 270 of the glass cap 250. FIG. 8B is a schematic diagram of the glass cap 250 showing an optional metallization layer 260.

An anti-reflective is applied coating to at least one of the second glass wafer 720 first surface 251 and second surface 252 before bonding the second glass wafer 720 to the first glass wafer 710. It is noted that in practice each of the surfaces 251, 252 of the substantially flat window 256 is advantageously flatter than any etched portion of the first portion 550 and is thus less likely to impart optical artifacts in a light beam conveyed through the substantially flat window 256 than, for example, a light beam conveyed through any etched surface of the first portion 550. For example, the second glass wafer first surface 251 and second surface 252 may each have a flatness of one micron or less, since the second glass wafer is not etched, while in comparison the etched surfaces of the glass cap have a flatness significantly greater than one micron as a result of the etching process. After singulation, the glass cap 250 may be attached to the substrate 220 (FIG. 2), as described previously.

Returning to FIG. 7C, it should be noted that additional glass caps 250 (FIG. 8A) may be released from the array of sealed pockets 790 by further singulation of the array of sealed pockets 790. For example, a glass cap 250 (FIG. 8A) may be released from the second sealed pocket 772 by an additional singulation along a fifth plane (not shown) parallel to the fourth plane 704, located between the second pocket 772 and a third pocket 773. Likewise, further additional glass caps 250 (FIG. 8A) may be released from array of sealed pockets 790 by additional singulations along planes parallel to the third plane 703 and/or parallel to the fourth plane 704.

While the above described embodiments have been directed to a package for a side emitting device, in alternative embodiments the package may be adapted for side facing packages configured to receive electromagnetic radiation instead of and/or in addition to emit electromagnetic radiation.

In summary, it will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for manufacturing a hermetic side looking laser surface-mount device (SMD) package, comprising the steps of:
forming a glass cap, comprising the steps of:
providing a first glass wafer comprising a first planar surface and a second planar surface substantially parallel to the first planar surface, the second planar surface disposed at a distance D from the first planar surface in a direction substantially normal to the first planar surface;
forming an array of pockets comprising a plurality of pockets in the first glass wafer first surface;
providing a second glass wafer comprising a first planar surface and a second planar surface substantially parallel to the first planar surface;
sealing the array of pockets by bonding the second glass wafer first surface to the first glass wafer first surface, wherein each of the plurality of pockets is enclosed by the first glass wafer and the second glass wafer;
defining in the sealed array of pockets a third plane normal to the first glass wafer first planar surface, the third plane substantially bisecting a row of the array of pockets;
defining in the sealed array of pockets a fourth plane normal to the first glass wafer first planar surface and normal to the third plane, the fourth plane disposed between a first pocket and a second pocket in the row of the array of pockets and not intersecting either of the first pocket and the second pocket; and
singulating the sealed array of pockets in the third plane and the fourth plane,
wherein a maximum depth of each pocket of the array of pockets into the first glass wafer with respect to the first glass wafer first surface is less than the distance D.

2. The method of claim 1, wherein the second glass wafer has a thickness less than the distance D.

3. The method of claim 1, further comprising the step of applying an anti-reflective coating to at least one of the second glass wafer first surface and second surface.

4. The method of claim 1, wherein the second glass wafer first surface and second surface each have a flatness of one micron or less.

5. The method of claim 1, further comprising the steps of:
forming a substrate comprising a component mounting surface and a package mounting surface;
forming a thermally and/or electrically conductive die attach pad on the component mounting surface of the substrate,
attaching a side-looking laser die to the conductive die attach pad; and
hermetically sealing the glass cap to the substrate over the side-looking laser die,
wherein the side-looking laser die is sealed within a cavity formed between the glass cap and the substrate.

6. The method of claim 5, further comprising the steps of:
forming a plurality of metalized pads on the substrate package mounting surface; and
forming a through via configured to provide electrical and/or thermal conductivity between the conductive die attach pad and at least one of the plurality of metalized pads.

7. The method of claim 5, wherein the side-looking laser die is arranged to emit a laser beam through a portion of the glass cap formed from the second glass wafer.

8. The method of claim 1, further comprising the steps of:
forming a substrate comprising a component mounting surface and a package mounting surface;
forming an electrically and/or thermally conductive metal laser array pedestal on the component mounting surface of the substrate;
forming a thermally and/or electrically conductive die attach pad on the metal laser array pedestal,
attaching a side-looking laser die to the conductive die attach pad; and
hermetically sealing the glass cap to the substrate over the side-looking laser die,
wherein the side-looking laser die is sealed within a cavity formed between the glass cap and the substrate.

9. The method of claim 8, further comprising the steps of:
forming a plurality of metalized pads on the substrate package mounting surface; and
forming a through via configured to provide electrical and/or thermal conductivity between the conductive die attach pad and at least one of the plurality of metalized pads.

10. The method of claim 8, wherein the side-looking laser die is arranged to emit a laser beam through a portion of the glass cap formed from the second glass wafer.

11. A side looking laser surface-mount device (SMD) package, comprising:
a carrier submount, comprising:
a semiconductor substrate comprising a substantially rectangular component mounting surface and a package mounting surface disposed opposite the component mounting surface;
an electrically conductive component mounting pad disposed on the component mounting surface;
an electrically conductive package mounting pad disposed on the package mounting surface in electrical communication with the component mounting pad; and
a side-looking laser die mounted to and in electrical communication with the component mounting pad, the side-looking laser die arranged to emit a laser beam in a path substantially parallel to the component mounting surface toward a first edge of the component mounting surface; and
a glass cap mounted to the laser submount over the laser die comprising;
a mounting surface surrounding a glass cap mounting surface cavity; and
an egress window mounted adjacent to the component mounting surface first edge,
wherein the glass cap is arranged upon the laser submount such that the side-looking laser die is disposed within the glass cap cavity and the laser beam path passes through the egress window.

12. The package of claim 11, further comprising:
a plurality of metalized pads disposed on the substrate package mounting surface; and
a through via disposed through the substrate configured to provide electrical and/or thermal conductivity between the conductive die attach pad and at least one of the plurality of metalized pads.

13. The package of claim 11, wherein the attached glass cap forms a hermetic seal of the laser die.

14. The package of claim 11, further comprising:
an electrically and/or thermally conductive pedestal portion disposed between the side-looking laser die and the semiconductor substrate configured to elevate the laser die with respect to the semiconductor substrate.

15. The package of claim 14, wherein the attached glass cap forms a hermetic seal of the laser die.

16. The package of claim 11, wherein the egress window comprises an interior surface bounding a portion of the glass cap mounting surface cavity and an exterior surface opposite the interior surface, and the interior surface and the exterior surface each have a flatness of one micron or less.
